(19) United States
(12) Patent Application Publication
(10) Pub. No.: US 2007/0269598 A1
(43) Pub. Date: Nov. 22, 2007

(54) METHOD, APPARATUS AND STARTING MATERIAL FOR PROVIDING A GASEOUS PRECURSOR

(76) Inventors: Alfred Kersch, Putzbrunn (DE); Angela Link, Munich (DE); Jonas Sundqvist, Dresden (DE); Elke Erben, Dresden (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/750,073

(22) Filed: May 17, 2007

(30) Foreign Application Priority Data
May 17, 2006 (DE) DE 10 2006 023 04

(51) Int. Cl. C23C 16/00

(52) U.S. Cl. 427/249.1

(57) ABSTRACT

A method and apparatus for providing a gaseous precursor for a coating process. A starting material having a pulverulent precursor material is heated in order to cause a vaporization of the pulverulent precursor material, whereby a gaseous precursor is produced. A carrier gas is flowed past the starting material at a distance minimizing or preventing a convective gas flow, while transporting the gaseous precursor to a processing region containing a wafer to be coated.

### CROSS-REFERENCE TO RELATED APPLICATIONS

This application claims foreign priority benefits under 35 U.S.C. §119 to co-pending German patent application number DE 10 2006 023 046.9-45, filed May 17, 2006. This related patent application is herein incorporated by reference in its entirety.

### BACKGROUND OF THE INVENTION

Different coating processes are used in order to produce thin coatings on semiconductor wafers. One such coding process is known as chemical vapor deposition (CVD). In this method, a semiconductor wafer to be coated is introduced into a process chamber of a so-called CVD reactor, in order, in a chemically reactive gas environment, to deposit the desired coating from the gas phase onto a surface of the semiconductor wafer. The starting substances, which are also denoted as precursors and which comprise the elements of the coating to be deposited, are introduced into the process chamber in the gaseous state in this case. The precursors may be activated by thermal heating in order to produce the precursor molecules suitable for depositing the coating on the surface of the semiconductor wafer.

A further exemplary process for producing coatings is the so called atomic layer deposition (ALD). In contrast to the CVD method, the ALD method substantially utilizes the chemical affinity of the surface of a semiconductor wafer that is to be coated to the individual precursor molecules or radicals. These are precipitated from the gas phase onto the surface of the semiconductor wafer until all the free valences are saturated. The deposition is therefore self-limiting and terminated.

The provision of a gaseous precursor for use in ALD deposition and CVD deposition methods (such as, for example, MOCVD (Metal Organic CVD)) for producing coatings that consist of “new materials” currently favored by the semiconductor industry such as, for example, high-k dielectrics, requires the use of starting materials present in the solid state phase. Such starting materials are transformed into the gaseous aggregate state by vaporization or sublimation in a vaporization apparatus upstream of a process chamber of an ALD or CVD reactor. However, these materials naturally have a low vapor pressure and a low vaporization rate.

In order, nevertheless, to provide the quantity of gaseous precursor required for a coating process, the starting material may be pulverized in order to enlarge the solid state surface available for the vaporization. In addition, a vaporization may be carried out at a relatively high temperature that is limited by a limiting temperature at which thermal decomposition reactions of the starting material occur. Furthermore, an inert carrier gas may be led through the pulverulent starting material in order to provide the gaseous precursor.

By way of example, U.S. Pat. No. 6,280,793 B1 discloses a method for providing a gaseous precursor for a coating process in which a pulverulent precursor material is firstly electrically charged and subsequently sprayed into a vaporization chamber of a vaporization apparatus with a heating element having an opposite charge. In this case, a further pulverulent solid state material, acting as carrier material, may be added to the pulverulent precursor material. Because of the opposite charges, particles or powder grains of the pulverulent precursor material are precipitated onto the heating element and vaporized. At the same time, a carrier gas is led through the vaporization chamber in order to feed the gaseous precursor produced in this way to a process chamber for a coating process.

Because of the electrical charging of the pulverulent precursor material that is carried out before the vaporization, however, this method is attended by a relatively high outlay. Moreover, there is the risk of the carrier gas led through the powder transporting powder grains (also present in the solid state phase, in addition to the gaseous precursors) into the process chamber for the coating process. It is possible in this way for a undesirable formation of particles to occur on a semiconductor wafer to be coated.

This problem may also occur in the vaporization method disclosed in US 2005/0019026 A1, in which a pulverulent starting material is fed to a vaporization container of a vaporization apparatus and is heated up for a vaporization. In a corresponding way, there is introduced into the vaporization container an inert carrier gas that mixes with the gaseous precursors and transports them into a process chamber for a coating process. In the case of this method, there is the risk of a convective gas flow; that is to say, a gas flow that entrains powder grains, in the region of the starting material.

Another problem that may arise with some pulverulent precursor materials, is that powder grains join together to form relatively large clumps at the vaporization temperature. This process, denoted as coalescence, is attended by a reduction in the surface available for the vaporization, the result being that the vaporization rate is reduced.

Accordingly there is a need for methods, apparatus and starting materials for providing a gaseous precursor.

### SUMMARY OF THE INVENTION

A method and apparatus for providing a gaseous precursor for a coating process. A starting material having a pulverulent precursor material is heated in order to cause a vaporization of the pulverulent precursor material, whereby a gaseous precursor is produced. A carrier gas is flowed past the starting material at a distance minimizing or preventing a convective gas flow, while transporting the gaseous precursor to a processing region containing a wafer to be coated.

In another embodiment, a method of making a starting material for providing a gaseous precursor in a wafer deposition process is provided. The method includes selecting a pulverulent precursor material according to desired vaporization characteristics of the pulverulent precursor material for a predefined vaporization environment upstream from a processing region in which the wafer deposition process is performed. The method further includes selecting a pulverulent inert solid state material according to desired vaporization characteristics of the pulverulent inert solid state material relative to the vaporization characteristics of the pulverulent precursor material. The method further includes combining the selected pulverulent precursor material with the pulverulent inert solid state material to produce the starting material.

### BRIEF DESCRIPTION OF THE DRAWINGS

Various features of embodiments will become clear from the following description, taking in conjunction with the accompanying drawings. It is to be noted, however, that the accompanying drawings illustrate only typical embodiments and are, therefore, not to be considered limiting of the scope of the invention. The present invention may admit other equally effective embodiments.

FIG. 1 shows a schematic illustration of a vaporization apparatus;

FIG. 2 shows a flowchart of a method for providing a gaseous precursor; and

FIG. 3 shows an enlarged schematic illustration of a container of the vaporization apparatus of FIG. 1, with a starting material.

### DETAILED DESCRIPTION OF THE PREFERRED EMBODIMENT

One embodiment of the present invention provides a method for providing a gaseous precursor for a coating process. The method includes providing a starting material which has a pulverulent precursor material, heating the starting material in order to cause a vaporization of the pulverulent precursor material, and conducting a carrier gas past the starting material at a distance sufficient to prevent a convective gas flow.

The precursor provided may have no particles present in the solid state phase, since the carrier gas is conducted past the starting material at a distance such as to avoid a convective gas flow in the region of the starting material; that is to say, the distance is sufficient to avoid a gas flow entraining particles of the pulverulent starting material. As a result of this, a deleterious formation of particles on a surface of a semiconductor wafer that is to be coated may be avoided in a coating process subsequently carried out.

The carrier gas may be conducted past the starting material in such a way that a substantially one-dimensional laminar flow of the carrier gas is produced at a prescribed distance from the starting material. Instances of turbulence of the carrier gas in the vicinity of the starting material, and an associated transportation of precursor particles by the carrier gas may be prevented in this way with a high degree of reliability.

While the carrier gas may be flowed at a distance and in a manner (relative to the starting material) sufficient to avoid entraining any precursor particles, in some cases the coating process to be performed on a wafer may be tolerant of some amount of precursor particles. In such cases it may not be necessary to avoid entraining any precursor particles, but only to avoid entraining an excessive amount of precursor particles. Accordingly, according to one embodiment, the distance and manner in which the carrier gas is flowed relative to the starting material may depend on the particular coating process and the desired film characteristics.

A starting material for use in a method for providing a gaseous precursor for a coating process comprises a mixture of a pulverulent precursor material and a pulverulent inert solid state material. It is possible with the aid of such a starting material to avoid (or mitigate) a coalescence, occurring during the vaporization of the pulverulent precursor material, of particles or powder grains to form clumps, which is associated with a reduction in the solid state surface available for the vaporization, and thus with a reduction in the vaporization rate.

In the starting material, particles of the pulverulent precursor material may be substantially surrounded by particles of the pulverulent inert solid state material. In this way suppression of the clumping of particles of the pulverulent precursor material may be achieved with a high degree of reliability.

To this end, a mixing ratio between the pulverulent precursor material and the pulverulent inert solid state material may be in a range from 1:2 to 1:10.

Furthermore, particles of the pulverulent precursor material may be of substantially the same size as particles of the pulverulent inert solid state material.

An apparatus for providing a gaseous precursor for a coating process comprises a container for holding a starting material having a pulverulent precursor material, a heating device for heating the starting material in order to cause a vaporization of the pulverulent precursor material, and an inlet opening and an outlet opening formed at the container for conducting a carrier gas past the starting material at a distance mitigating or preventing a convective gas flow.

Such an apparatus may prevent an entrainment of particles of the starting material by the carrier gas. Consequently, the undesirable formation of particles on a semiconductor wafer to be coated may be mitigated or avoided in the case of a coating process carried out subsequent to the vaporization of the pulverulent precursor material.

Further embodiments for providing a gaseous precursor are explained in conjunction with the drawings.

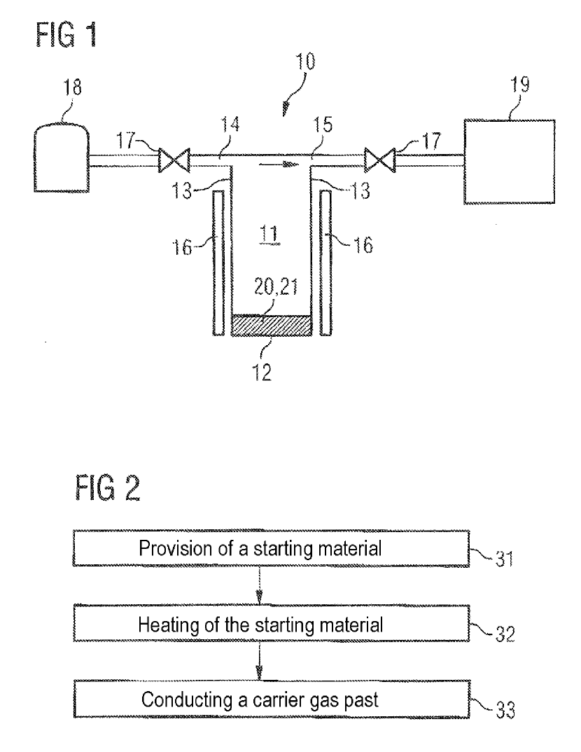

FIG. 1 shows a schematic illustration of a vaporization apparatus 10 in the case of which the method, illustrated in FIG. 2, for providing a gaseous precursor for a coating process may be applied. The coating process may, for example, be a CVD or an ALD deposition process with the aid of which a carrier, for example a semiconductor wafer, is coated.

In the method illustrated in FIG. 2, there is initially provided in a first method step 31 a starting material 20 that comprises at least partially a pulverulent precursor material 21. A starting material 20 provided in such a way is held in a container 11 in the vaporization apparatus 10 of FIG. 1. The container 11 may have a substantially rectangular cross section with a container bottom 12 and side walls 13, the horizontal dimensions of the container 11 being, for instance, smaller than the vertical dimensions. The starting material 20 is held in this case in the region of the container bottom 12.

In a subsequent method step 32 of the method illustrated in FIG. 2, the starting material 20 is heated in order to cause a vaporization of the pulverulent precursor material 21. To this end, the vaporization apparatus 10 illustrated in FIG. 1 has heating elements 16 that are arranged around the side walls 13 of the container 11 and are, for example, designed as heating resistors. The heating elements 16 may optionally be designed in another way, for example, as inductive heating coils.

The heating elements 16 are used to heat up the starting material 20 to a prescribed vaporization temperature at which an adequate vaporization of the pulverulent precursor material 21 is attained. The vaporization temperature is below a decomposition temperature or a liquefaction temperature of the precursor material 21, in order to avoid a decomposition or liquefaction of the precursor material 21.

In accordance with a further method step 33 of the method illustrated in FIG. 2, an inert carrier gas is conducted past the starting material 20 in order to provide the gaseous precursor, emerging from the vaporization of the precursor material 21, for a coating process carried out in a process chamber 19 of a reactor. The carrier gas is conducted past in this case at a distance from the starting material 20 such as to avoid a convective gas flow in the vicinity of the starting material 20, that is to say a gas flow entraining solid state particles of the pulverulent starting material 20.

To this end, the container 11 of the vaporization apparatus 10 illustrated in FIG. 1 has an inlet opening 14 and an outlet opening 15 that are fashioned in the side walls 13 of the container 11 at a spacing from the container bottom 12. The inlet opening 14 is connected via an appropriate gas line to a gas reservoir or gas container 18 in which the carrier gas is stored under pressure. The outlet opening 15 is connected via a further gas line to the process chamber 19 for carrying out the coating process. The feed flow of the carrier gas into the container 11, and the exhaust flow of the carrier gas, saturated with the gaseous precursor, from the container 11 may be set via valves 17 arranged in the gas lines. Moreover, it is possible to provide a pumping device (not illustrated in FIG. 1) in order to control the feed flow and exhaust flow of the carrier gas.

The inlet opening 14 and the outlet opening 15 may be formed substantially opposite one another in the side walls 13 of the container 11, as illustrated in FIG. 1. It is possible in this way to conduct the carrier gas past the starting material 20 in such a way that a substantially one-dimensional laminar flow of the carrier gas is produced at a prescribed distance from the starting material 20. The consequence of such a gas flow, which is indicated in FIG. 1 by the arrow illustrated between the inlet opening 14 and the outlet opening 15, is that instances of turbulence in the carrier gas may be avoided in the vicinity of the starting material 20. A transportation of precursor particles from the container 11 into the process chamber 19 by the carrier gas, which leads to the formation of particles on a surface, which is to be coated, of a carrier or a semiconductor wafer introduced into the process chamber 19, may be prevented with a high degree of reliability in this way.

Instead of forming the inlet opening 14 and the outlet opening 15 at the upper end of the side walls 13 of the container 11, as illustrated in FIG. 1, the inlet opening 14 and the outlet opening 15 may also be formed in the side walls 13 at another location. In such embodiments of a container 11, the inlet opening 14 and the outlet opening 15 may also be arranged substantially opposite one another, in order to cause a substantially one-dimensional laminar flow of the carrier gas.

The pulverulent precursor material 21 may have a metal, for example from the group of Hf, Zr, Ru, La, Pr, in order to provide a so-called metal precursor comprising said metals for the production of corresponding metal coatings. In this case, the corresponding metal compounds may be present in the precursor material 21 in the form of tetrachloride compounds, for example; that is to say as HfCl₄ in the case of Hf, for example. Argon or nitrogen, for example, may be used as inert carrier gas for such metal precursors.

In addition to the gas line that is illustrated in FIG. 1 and connects the container 11 to the process chamber 19, it is also possible to provide further gas lines connected to the process chamber 19, in order to feed further gaseous precursors to the process chamber 19 from further vaporization apparatuses for a coating process. An additional gas line may, for example, be used also to introduce a so-called oxide precursor containing oxygen such as water vapor, for example, into the process chamber 19 in addition to the above-named metal precursor.

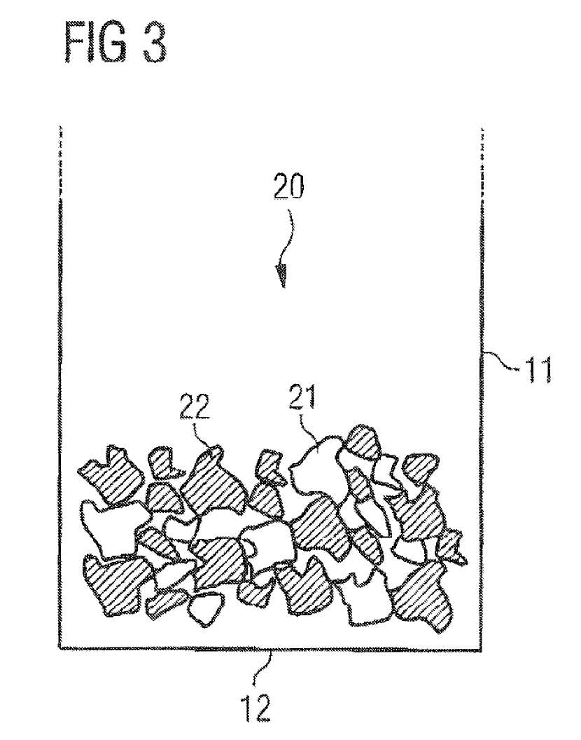

Instead of using a starting material 20 consisting exclusively of a pulverulent precursor material 21, the starting material 20 may have a mixture of a pulverulent precursor material 21 and a pulverulent inert solid state material 22, as may be seen with the aid of the enlarged illustration of the container 11 of the vaporization apparatus 10 depicted in FIG. 3. Here, the pulverulent inert solid state material 22 may have particles of quartz sand or SiO₂, Si and/or silicon nitride.

It is possible with the aid of such a starting material 20 to avoid a clumping, denoted as coalescence, of particles or crystallites of the pulverulent precursor material 21, occurring during the vaporization of the pulverulent precursor material 21, which is associated with a reduction in the solid state surface available for the vaporization, and consequently with a reduction in the vaporization rate. For the purpose of effectively preventing a clumping of particles of the precursor material 21, the particles of the precursor material 21 may in this case be substantially surrounded by particles of the inert solid state material 22; that is to say each crystallite of the precursor material 21 may be surrounded, at least in part, by crystallites of the solid state material 22.

To this end, the starting material 20 may have a mixing ratio between the pulverulent precursor material 21 and the pulverulent inert solid state material 22 in a range from 1:2 to 1:10. Furthermore, the particles of the pulverulent precursor material 21 may substantially be of the same size as particles of the pulverulent inert solid state material 22, in order to enable a diffusive transportation, unimpeded as far as possible, of gaseous precursor molecules in the porous starting material 20.

When a quantity of starting material 20 in a range from, for example, 5 g to 10 g is used, both the particles of the precursor material 21 and the particles of the inert solid state material 22 may be of a size in a range from 30 μm to 500 μm. This both makes available an overall surface adequate for the vaporization, and enables thorough mixing of particles of the precursor material 21 and particles of the solid state material 22.

The melting point of the pulverulent inert solid state material 22 may be substantially higher than the melting point of the pulverulent precursor material 21. For a precursor material 21 having, for example, HfCl₄ and a melting temperature of 319° C., this precondition is met in the case of an inert solid state material 22 made, for example, from SiO₂ with a melting temperature of 1723° C., or Si with a melting temperature of 1410° C. This may avoid a liquefaction of the solid state material 22 that impairs the vaporization of the precursor material 21.

The preceding description describes exemplary embodiments of the invention. The features disclosed therein and the claims and the drawings can, therefore, be useful for realizing the invention in its various embodiments, both individually and in any combination. While the foregoing is directed to embodiments of the invention, other and further embodiments of this invention may be devised without departing from the basic scope of the invention, the scope of the present invention being determined by the claims that follow.

What is claimed is:

1. A method for providing a gaseous precursor for a coating process to be performed in a processing region, comprising:
providing a starting material comprising a pulverulent precursor material;
heating the starting material in order to cause a vaporization of the pulverulent precursor material to produce the gaseous precursor; and
conducting a carrier gas past the starting material at a selected distance in order to transport the gaseous precursor to the processing region, wherein the distance is selected to at least minimize a convective gas flow causing entrainment of particulate from the starting material.

2. The method according to claim 1, wherein the carrier gas is conducted past the starting material in such a way that a substantially one-dimensional laminar flow of the carrier gas is produced at a prescribed distance from the starting material.

3. A method of making a starting material for providing a gaseous precursor in a wafer deposition process, comprising:
selecting a pulverulent precursor material according to desired vaporization characteristics of the pulverulent precursor material for a predefined vaporization environment upstream from a processing region in which the wafer deposition process is performed;
selecting a pulverulent inert solid state material according to desired vaporization characteristics of the pulverulent inert solid state material relative to the vaporization characteristics of the pulverulent precursor material; and
combining the selected pulverulent precursor material with the pulverulent inert solid state material to produce the starting material.

4. The method according to claim 3, wherein particles of the pulverulent precursor material are substantially surrounded by particles of the pulverulent inert solid state material.

5. The method according to claim 3, wherein combining the selected pulverulent precursor material with the pulverulent inert solid state material is done at a mixing ratio between the pulverulent precursor material and the pulverulent inert solid state material in a range from 1:2 to 1:10.

6. The method according to claim 3, wherein particles of the pulverulent precursor material are of substantially the same size as particles of the pulverulent inert solid state material.

7. The method according to claim 3, wherein a size of particles of the pulverulent precursor material and of particles of the pulverulent inert solid state material is in a range from 30 μm to 500 μm.

8. The method according to claim 3, wherein the melting point of the pulverulent inert solid state material is substantially higher than the melting point of the pulverulent precursor material.

9. The method according to claim 3, wherein the pulverulent precursor material comprises a metal.

10. The method according to claim 3, wherein the pulverulent precursor material comprises one of the group of: Hf, Zr, Ru, La, Pr.

11. The method according to claim 3, wherein the pulverulent inert solid state material comprises SiO₂, Si and/or silicon nitride.

12. An apparatus for providing a gaseous precursor for a wafer deposition process to be performed in a processing region, comprising:
a container for holding a starting material comprising a pulverulent precursor material;
a heating device for heating the starting material in order to cause vaporization of the pulverulent precursor material to produce the gaseous precursor; and
an inlet opening and an outlet opening formed at the container for conducting a carrier gas past the starting material at a selected distance in order to transport the gaseous precursor to the processing region at which the wafer deposition process, wherein the distance is selected to at least minimize a convective gas flow causing entrainment of particulate from the starting material.

13. The apparatus according to claim 12, wherein the container comprises a substantially rectangular cross section with a container bottom and side walls, the starting material being disposed on the container bottom, and the inlet opening and the outlet opening being formed in the side walls of the container at a spacing from the container bottom.

14. The apparatus according to claim 12, wherein the inlet opening and the outlet opening are formed substantially opposite one another in side walls of the container, in order to conduct the carrier gas past the starting material in such a way that a substantially one-dimensional laminar flow of the carrier gas is produced at the selected distance from the starting material.

15. The apparatus according to claim 12, wherein the inlet opening and the outlet opening are formed at an upper end of side walls of the container
